(19) United States
(12) Patent Application Publication
(10) Pub. No.: US 2023/0018651 A1
(43) Pub. Date: Jan. 19, 2023

(54) REGULATOR CIRCUIT AND CONTROL CIRCUIT OF DC/DC CONVERTER

(71) Applicant: ROHM Co., LTD., Kyoto (JP)

(72) Inventor: Akihiro KAWANO, Kyoto (JP)

(21) Appl. No.: 17/812,376

(22) Filed: Jul. 13, 2022

(30) Foreign Application Priority Data
Jul. 16, 2021 (JP) 2021-118077

(51) Int. Cl. H02M 3/158; H02M 1/08; G05F 1/575; H03F 3/45; H03G 3/30; G05F 1/565

(52) U.S. Cl. CPC H02M 3/158; H02M 1/08; G05F 1/575; H03F 3/45; H03G 3/30; G05F 1/565

(57) ABSTRACT

Provided is a regulator circuit that supplies an output voltage to a load, the regulator circuit including an error amplifier that amplifies an error between a feedback signal and a reference voltage, and an output stage that changes the output voltage, the error amplifier including a first transconductance amplifier that receives the feedback signal and the reference voltage, a first resistance connected to an output node of the first transconductance amplifier and a ground, a first capacitor connected in parallel to the first resistance, a second transconductance amplifier that receives a voltage of the output node of the first transconductance amplifier and the feedback signal, a second resistance connected to an output node of the second transconductance amplifier and a ground, a second capacitor connected in parallel to the second resistance, and a zero controller that controls a gain of the second transconductance amplifier.

### CROSS REFERENCE TO RELATED APPLICATIONS

This application claims priority benefit of Japanese Patent Application No. JP 2021-118077 filed in the Japan Patent Office on Jul. 16, 2021. Each of the above-referenced applications is hereby incorporated herein by reference in its entirety.

### BACKGROUND

The present disclosure relates to a regulator circuit.

A regulator circuit that generates a stable voltage with a small voltage change is used in various electronic devices, such as consumer products including a smartphone and a tablet computer, in-vehicle devices, office automation (OA) equipment, and industrial equipment. The regulator circuit is broadly classified into a switching regulator and a linear regulator circuit.

Feedback by an error amplifier stabilizes the output voltage of the regulator circuit at a target level. Phase compensation may be necessary for stable operation of the regulator circuit without oscillation.

FIG. 1 is a diagram describing the phase compensation in the linear regulator circuit. A linear regulator circuit 10 includes an error amplifier 12, resistances R11 and R12, an output transistor 14, and an output capacitor 16. A load 20 is connected to the output of the linear regulator circuit 10. Parallel connection of the load 20 and the output capacitor 16 generates a pole ωₚ.

ωₚ=1/(Cout·Rout) (1)

Cout represents a capacitance of the output capacitor 16, and Rout represents an impedance of the load 20.

A phase compensation circuit is implemented in the error amplifier 12 to cancel the influence of the pole ωₚ. The phase compensation circuit adds zero to an appropriate position with respect to a certain pole ωₚ to prevent a phase lead.

The same applies to the switching regulator, and the phase compensation circuit is implemented in the error amplifier.

An example of the related art is disclosed in PCT Patent Publication No. WO2021/124910.

### SUMMARY

As can be understood from Equation (1), the pole frequency ωₚ is dependent on the load impedance. Accordingly, the pole frequency ωₚ changes in an application with a dynamically changing load impedance. In such a case, the circuit constants of the phase compensation circuit may need to be determined to satisfy the stability conditions for all assumed poles ωₚ, making it difficult to design the circuit.

According to an embodiment of the present disclosure, it is desirable to provide a regulator circuit or a control circuit of a direct current/direct current (DC/DC) converter capable of performing stable operation with respect to a dynamically changing load.

A mode of the present disclosure relates to a regulator circuit that supplies an output voltage to a load. The regulator circuit includes an error amplifier that amplifies an error between a feedback signal corresponding to the output voltage and a reference voltage, and an output stage that changes the output voltage according to an output of the error amplifier. The error amplifier includes a first transconductance amplifier that receives the feedback signal and the reference voltage, a first resistance connected to an output node of the first transconductance amplifier and a ground, a first capacitor connected in parallel to the first resistance, a second transconductance amplifier that receives a voltage of the output node of the first transconductance amplifier and the feedback signal, a second resistance connected to an output node of the second transconductance amplifier and a ground, a second capacitor connected in parallel to the second resistance, and a zero controller that controls a gain of the second transconductance amplifier according to an output current of the regulator circuit.

Another mode of the present disclosure also provides a regulator circuit. The regulator circuit includes an error amplifier that amplifies an error between a feedback signal corresponding to an output voltage and a reference voltage, and an output stage that changes the output voltage according to an output of the error amplifier. The error amplifier includes a first amplifier of a high-gain narrow-band and a second amplifier of a low-gain broadband that are connected in cascade, and a zero controller that controls a gain of the second amplifier according to an output current of the regulator circuit.

Yet another mode of the present disclosure relates to a control circuit of a DC/DC converter. The control circuit includes an error amplifier that amplifies an error between a feedback signal corresponding to an output voltage of the DC/DC converter and a reference voltage, and a pulse modulator that generates a pulse signal according to an output of the error amplifier. The error amplifier includes a first transconductance amplifier that receives the feedback signal and the reference voltage, a first resistance connected to an output node of the first transconductance amplifier and a ground, a first capacitor connected in parallel to the first resistance, a second transconductance amplifier that receives a voltage of the output node of the first transconductance amplifier and the feedback signal, a second resistance connected to an output node of the second transconductance amplifier and a ground, a second capacitor connected in parallel to the second resistance, and a zero controller that controls a gain of the second transconductance amplifier according to an output current of the DC/DC converter.

Yet another mode of the present disclosure also provides a control circuit of a DC/DC converter. The control circuit includes an error amplifier that amplifies an error between a feedback signal corresponding to an output voltage of the DC/DC converter and a reference voltage, and a pulse modulator that generates a pulse signal according to an output of the error amplifier. The error amplifier includes a first amplifier of a high-gain narrow-band and a second amplifier of a low-gain broadband that are connected in cascade, and a zero controller that controls a gain of the second amplifier according to an output current of the DC/DC converter.

Note that any combinations of the constituent elements as well as constituent elements and expressions obtained by exchanging the constituent elements and the expressions among methods, apparatuses, and systems are also effective as modes of the present technology.

According to the modes of the present disclosure, the stability of the regulator circuit can be improved.

### BRIEF DESCRIPTION OF THE DRAWINGS

FIG. 1 is a diagram describing phase compensation in a linear regulator circuit;

FIG. 2 is a block diagram of an electronic device including a regulator circuit according to embodiments;

FIG. 3 is a diagram describing frequency characteristics (gain characteristics) of an error amplifier;

FIG. 4 is a diagram describing an operation of the regulator circuit illustrated in FIG. 2;

FIG. 5 is a circuit diagram of a regulator circuit according to a first embodiment;

FIG. 6 is a circuit diagram illustrating a configuration example of an error amplifier;

FIG. 7 is a circuit diagram illustrating a configuration example of a second amplifier;

FIG. 8 is a circuit diagram illustrating a configuration example of a zero controller;

FIG. 9 is a circuit diagram of a regulator circuit according to a second embodiment;

FIG. 10 is an operation waveform diagram of a buck DC/DC converter that operates in a discontinuous conduction mode (DCM); and

FIG. 11 depicts an example of an electronic device including the regulator circuit according to the embodiments.

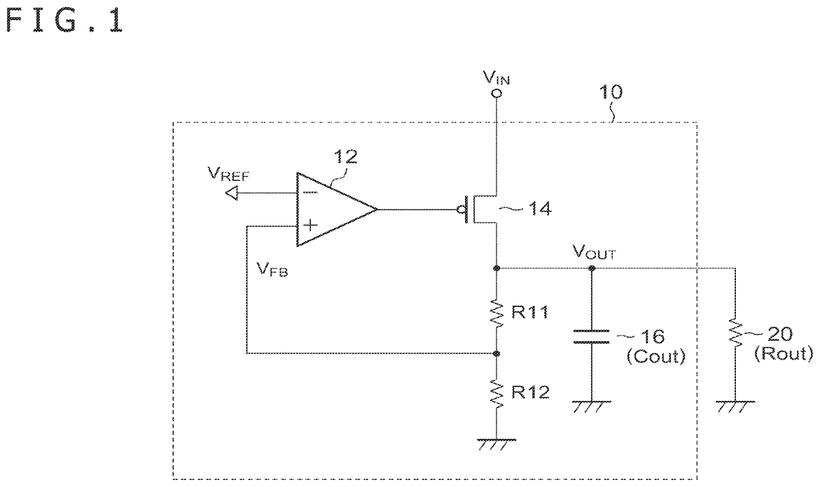

### DETAILED DESCRIPTION OF THE PREFERRED EMBODIMENTS

### Overview of Embodiments

An overview of some exemplary embodiments of the present disclosure will be described. The overview briefly describes some concepts of one or a plurality of embodiments for basic understanding of the embodiments as a preface to detailed explanation described later, and the overview does not limit the extent of the technology or the disclosure. The overview is not a comprehensive overview of all possible embodiments, and the overview is not intended to specify important elements of all the embodiments or to define the scope of part or all of the modes. For convenience, “one embodiment” may be used to represent one embodiment (example or modification) or a plurality of embodiments (examples or modifications) disclosed in the present specification.

A regulator circuit according to an embodiment supplies an output voltage to a load. The regulator circuit includes an error amplifier that amplifies an error between a feedback signal corresponding to the output voltage and a reference voltage, and an output stage that changes the output voltage according to an output of the error amplifier. The error amplifier includes a first transconductance amplifier that receives the feedback signal and the reference voltage, a first resistance connected to an output node of the first transconductance amplifier and a ground, a first capacitor connected in parallel to the first resistance, a second transconductance amplifier that receives a voltage of the output node of the first transconductance amplifier and the feedback signal, a second resistance connected to an output node of the second transconductance amplifier and a ground, a second capacitor connected to the output node of the second transconductance amplifier, in parallel to the second resistance, and a zero controller that controls a gain of the second transconductance amplifier according to an output current of the regulator circuit.

In a regulator circuit with constant voltage output, the output current of the regulator circuit is inversely proportional to the impedance of the load. The pole shifts to the low frequency side when the impedance of the load becomes large. In this case, the output current decreases, and the gain of the second transconductance amplifier can be increased accordingly to shift the zero point of the error amplifier to the low frequency side. This allows adaptive phase compensation according to the load change.

In an embodiment, the zero controller may successively change a bias current of the second transconductance amplifier according to the output current of the regulator circuit. The bias current can be successively changed to successively move the zero point in association with the pole.

In an embodiment, the smaller the output current of the regulator circuit is, the more the zero controller may increase the bias current of the second transconductance amplifier.

In an embodiment, the regulator circuit may be a linear regulator circuit. The output stage may include an output transistor. The zero controller may include a first transistor with a gate and a source connected in common to a gate and a source of the output transistor, and a correction current generation circuit that generates a correction current corresponding to a current flowing through the first transistor and that supplies the correction current to the second transconductance amplifier.

In an embodiment, the regulator circuit may be a DC/DC converter. The zero controller may change the bias current of the second transconductance amplifier according to an output current of the DC/DC converter when the DC/DC converter operates in a discontinuous conduction mode.

A regulator circuit according to an embodiment includes an error amplifier that amplifies an error between a feedback signal corresponding to an output voltage and a reference voltage, and an output stage that changes the output voltage according to an output of the error amplifier. The error amplifier includes a first amplifier of a high-gain narrow-band and a second amplifier of a low-gain broadband that are connected in cascade, and a zero controller that controls a gain of the second amplifier according to an output current of the regulator circuit. Here, the high gain and the low gain are relative, and the narrow band and the broadband are relative.

In this configuration, the pole of the first amplifier and the pole of the second amplifier are combined, and the frequency characteristics of the error amplifier include pseudo one pole and one zero. The zero point shifts to the low frequency side when the gain of the second amplifier of the low-gain broadband is increased. The zero point shifts to the high frequency side when the gain of the second amplifier is reduced. Therefore, the zero point can be shifted in association with the movement of the pole associated with the load change.

In an embodiment, the second amplifier may include a second transconductance amplifier, a second resistance connected to an output node of the second transconductance amplifier, and a second capacitor connected in parallel to the second resistance.

In an embodiment, the zero controller may control a gain of the second transconductance amplifier according to the output current of the regulator circuit.

In an embodiment, the zero controller may control an impedance of the second resistance according to the output current of the regulator circuit.

In an embodiment, the regulator circuit may be integrated into one semiconductor substrate. The “integration” includes a case in which all of the constituent elements of the circuit are formed on the semiconductor substrate and a case in which main constituent elements of the circuit are integrated. Some of resistances, capacitors, and other constituent elements for adjusting the circuit constants may be provided outside the semiconductor substrate. Integrating the circuit on one chip allows the circuit area to be reduced and the characteristics of the circuit elements to be kept uniform.

A control circuit of a DC/DC converter according to an embodiment includes an error amplifier that amplifies an error between a feedback signal corresponding to an output voltage of the DC/DC converter and a reference voltage, and a pulse modulator that generates a pulse signal according to an output of the error amplifier. The error amplifier includes a first transconductance amplifier that receives the feedback signal and the reference voltage, a first resistance connected to an output node of the first transconductance amplifier and a ground, a first capacitor connected in parallel to the first resistance, a second transconductance amplifier that receives a voltage of the output node of the first transconductance amplifier and the feedback signal, a second resistance connected to an output node of the second transconductance amplifier and a ground, a second capacitor connected in parallel to the second resistance, and a zero controller that controls a gain of the second transconductance amplifier according to an output current of the DC/DC converter.

In a DC/DC converter with constant voltage output, the output current of the DC/DC converter is inversely proportional to the impedance of the load. The pole shifts to the low frequency side when the impedance of the load becomes large. In this case, the output current decreases, and the gain of the second transconductance amplifier can be increased accordingly to shift the zero point of the error amplifier to the low frequency side. This allows adaptive phase compensation according to the load change.

A control circuit of a DC/DC converter according to an embodiment includes an error amplifier that amplifies an error between a feedback signal corresponding to an output voltage of the DC/DC converter and a reference voltage, and a pulse modulator that generates a pulse signal according to an output of the error amplifier. The error amplifier includes a first amplifier of a high-gain narrow-band and a second amplifier of a low-gain broadband that are connected in cascade, and a zero controller that controls a gain of the second amplifier according to an output current of the DC/DC converter.

In this configuration, the pole of the first amplifier and the pole of the second amplifier are combined, and the frequency characteristics of the error amplifier include pseudo one pole and one zero. The zero point shifts to the low frequency side when the gain of the second amplifier of the low-gain broadband is increased. The zero point shifts to the high frequency side when the gain of the second amplifier is reduced. Thus, the zero point can be shifted in association with the movement of the pole associated with the load change.

### Embodiments

The present disclosure will now be described in reference to preferred embodiments and the drawings. The same signs are provided to the same or equivalent constituent elements, members, and processes illustrated in the drawings, and duplicate description will appropriately be omitted. The embodiments are exemplary, and not intended to limit the technology or the disclosure. All features and combinations of the features described in the embodiments may not necessarily be essential for the technology or the disclosure.

In the present specification, “a state in which a member A and a member B are connected” includes a case in which the member A and the member B are physically and directly connected as well as a case in which the member A and the member B are indirectly connected through another member that does not substantially affect their electrical connection state and that does not impair the functions and the effects obtained by the coupling of them.

Similarly, “a state in which a member C is provided between a member A and a member B” includes a case in which the member A and the member C or the member B and the member C are directly connected as well as a case in which they are indirectly connected through another member that does not substantially affect their electrical connection state and that does not impair the functions and the effects obtained by the coupling of them.

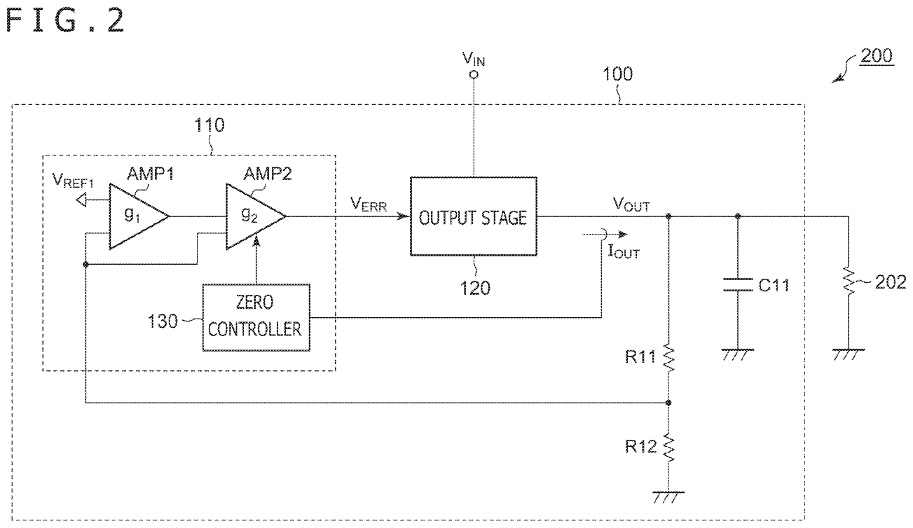

FIG. 2 is a block diagram of an electronic device 200 including a regulator circuit 100 according to the embodiments. The electronic device 200 includes a load 202 in addition to the regulator circuit 100. The load 202 is a device with a dynamically changing impedance. The load 202 may be, for example, a central processing unit (CPU), a micro controller, or other electronic parts. The load 202 may be a circuit block including a plurality of electronic parts.

The load 202 is connected to an output line of the regulator circuit 100. The regulator circuit 100 supplies the load 202 with an output voltage V_{OUT} stabilized at a predetermined voltage level V_{OUT(REF)}. The regulator circuit 100 may be a linear regulator or may be a DC/DC converter (switching regulator).

The regulator circuit 100 includes an error amplifier 110, an output stage 120, resistances R11 and R12, and an output capacitor C11.

The output voltage V_{OUT} is divided by the resistances R11 and R12, and a feedback signal V_{FB} is generated. The error amplifier 110 amplifies an error between the feedback signal V_{FB} and a reference voltage V_{REF}. The output stage 120 steps down or steps up an input voltage V_{IN} according to an output V_{ERR} of the error amplifier 110 to change the output voltage V_{OUT}. The output stage 120 has a configuration or topology corresponding to the type of regulator circuit 100.

The output voltage V_{OUT} is stabilized at the following target level V_{OUT(REF)} when the feedback loop is stable.

V_{OUT(REF)}−V_{REF}×(R11+R12)/R12

The error amplifier 110 includes a first amplifier AMP1, a second amplifier AMP2, and a zero controller 130 that are connected in cascade. The first amplifier AMP1 is designed to correspond to a relatively high gain narrow-band, and the second amplifier AMP2 is designed to correspond to a relatively low gain broadband. The gains of the first amplifier AMP1 and the second amplifier AMP2 will be referred to as g₁ and g₂, respectively.

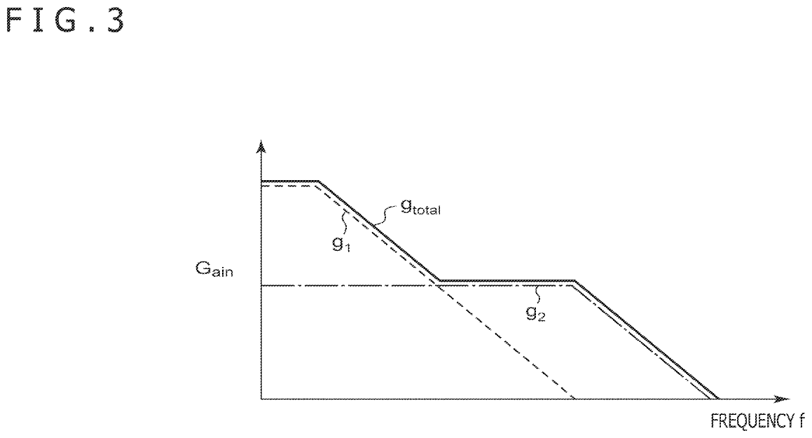

FIG. 3 is a diagram describing frequency characteristics (gain characteristics) of the error amplifier 110. A dashed line represents the gain g₁ of the first amplifier AMP1. A chain line represents the gain g₂ of the second amplifier AMP2. A solid line represents a gain gₜₒₜₐₗ of the entire error amplifier 110. As a result of combining the frequency characteristics of the two amplifiers AMP1 and AMP2, the frequency characteristics of the error amplifier 110 include pseudo one pole and one zero.

FIG. 2 will be further described. The zero controller 130 controls the gain g₂ of the second amplifier AMP2 corresponding to the low-gain broadband, according to an output current I_{OUT} of the regulator circuit 100. Specifically, the smaller the output current I_{OUT} is, the more the zero controller 130 will increase the gain g₂ of the second amplifier AMP2.

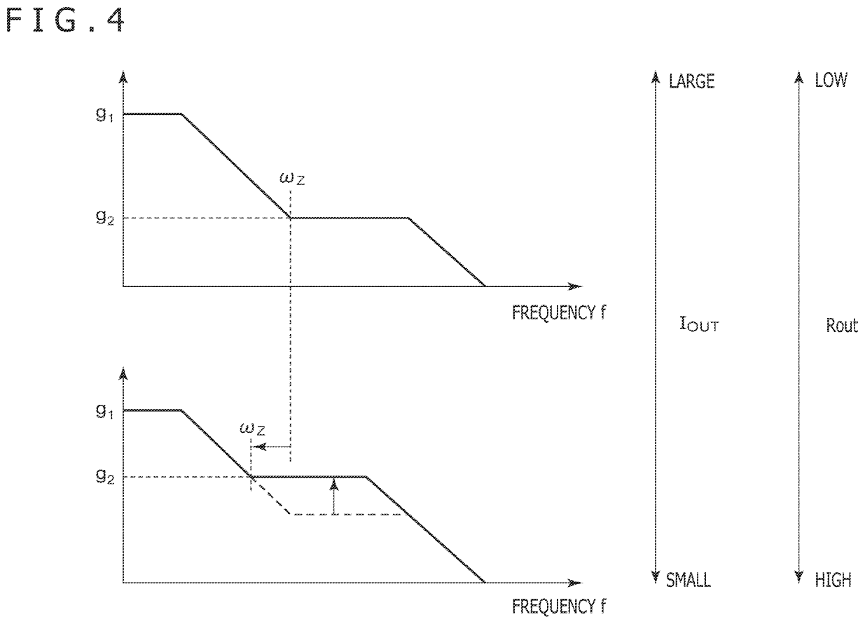

This completes the description regarding the configuration of the regulator circuit 100. Next, an operation of the regulator circuit 100 will be described. FIG. 4 is a diagram describing the operation of the regulator circuit 100 illustrated in FIG. 2. A zero point ω_{z} shifts to the low frequency side when the gain g₂ of the second amplifier AMP2 corresponding to the low-gain broadband is increased. On the other hand, the zero point ω_{z} shifts to the high frequency side when the gain g₂ of the second amplifier AMP2 is reduced.

A pole ωp₂ formed by the load 202 and the output capacitor C11 shifts to the low frequency side when the output current I_{OUT} decreases, in other words, when a load impedance Rout increases. A phase margin can be reserved by shifting of the zero point ω_{z} of the error amplifier 110 in association with the shift of the pole ωₚ₂.

The present disclosure applies to various apparatuses and methods figured out as the block diagram or the circuit diagram of FIG. 2 and to various apparatuses and methods derived from the above description, and the present disclosure is not limited to a specific configuration. More specific configuration examples and embodiments will now be described not to narrow down the scope of the present disclosure, but to help understanding of the essence and the operation of the present technology or clarification of the essence and the operation of the present technology.

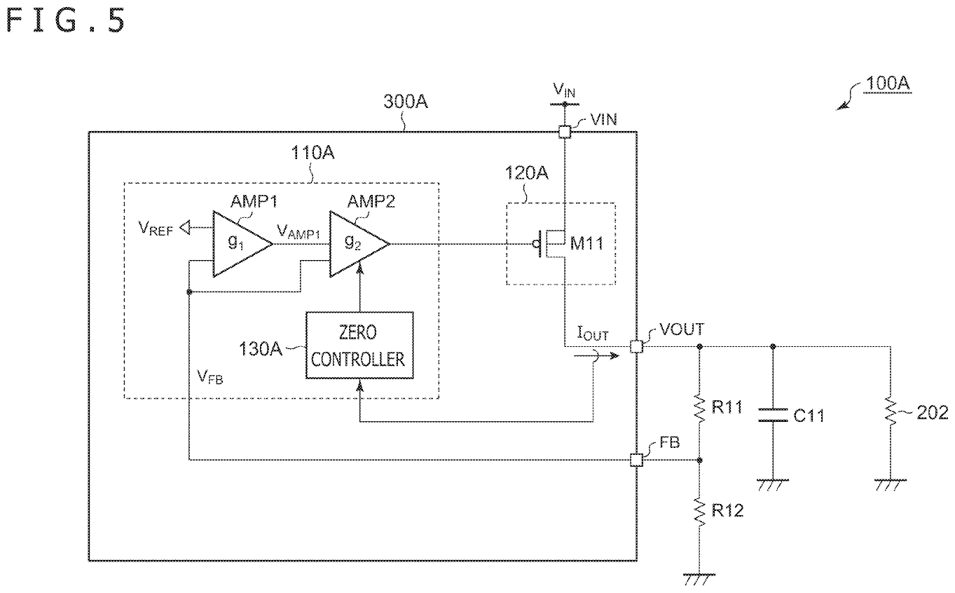

FIG. 5 is a circuit diagram of a regulator circuit (linear regulator circuit 100A) according to a first embodiment. Main parts of the linear regulator circuit 100A are integrated into a semiconductor chip 300A. The semiconductor chip 300A may be a chip dedicated to the linear regulator circuit 100A or may be a multi-channel power supply circuit such as a power management integrated circuit (PMIC).

Alternatively, the semiconductor chip 300A may be a general functional IC including a linear regulator, and in that case, the load 202 is integrated into the semiconductor chip 300A.

An error amplifier 110A and an output stage 120A are integrated into the semiconductor chip 300A. The output stage 120A includes an output transistor M11. Although the output transistor M11 is a P-channel metal oxide semiconductor field effect transistor (MOSFET) in the present embodiment, the output transistor M11 is not limited to this. The output transistor M11 may be an N-channel MOSFET or may be a PNP or NPN bipolar transistor. The output transistor M11 may be an external discrete element connected to the semiconductor chip 300A.

The error amplifier 110A generates the error voltage V_{ERR} to bring the feedback signal V_{FB} into line with the reference voltage V_{REF} and supplies a gate voltage V_{G} corresponding to the error voltage V_{ERR} to the gate of the output transistor M11. Although the error voltage V_{ERR} is directly input to the gate of the output transistor M11 in FIG. 5, the configuration is not limited to this, and another amplification stage or a buffer may be inserted between the second amplifier AMP2 and the output transistor M11. In that case, the amplification stage and the buffer may be part of the error amplifier 110A or may be part of the output stage 120A.

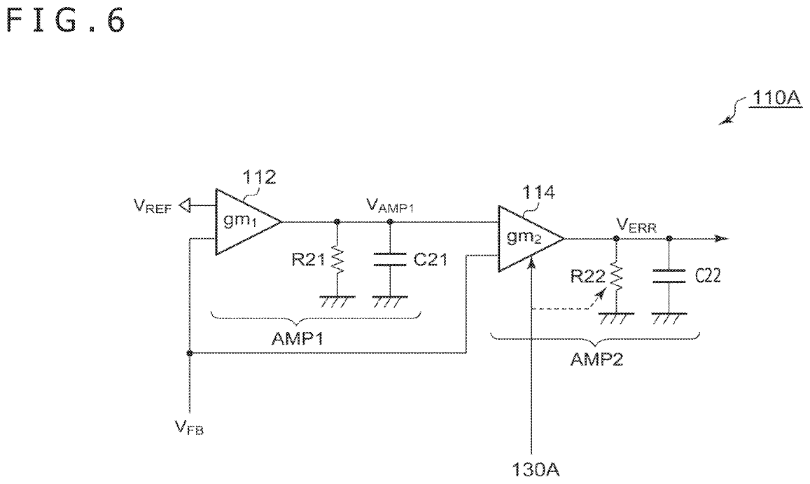

FIG. 6 is a circuit diagram illustrating a configuration example of the error amplifier 110A. The error amplifier 110A includes a first transconductance amplifier (gm amplifier) 112, a second transconductance amplifier 114, a first resistance R21, a second resistance R22, a first capacitor C21, a second capacitor C22, and a zero controller 130A. The first transconductance amplifier 112 receives the feedback signal V_{FB} and the reference voltage V_{REF}. The first resistance R21 and the first capacitor C21 are connected in parallel to the output node of the first transconductance amplifier 112 and the ground. The first transconductance amplifier 112, the first resistance R21, and the first capacitor C21 correspond to the first amplifier AMP1 illustrated in FIG. 5.

The second transconductance amplifier 114 receives a voltage V_{AMP1} of the output node of the first transconductance amplifier 112 and the feedback signal V_{FB}. The second resistance R22 is connected to the output node of the second transconductance amplifier 114 and the ground. The second capacitor C22 is connected to the output node of the second transconductance amplifier 114 and the ground, in parallel to the second resistance R22. The second transconductance amplifier 114, the second resistance R22, and the second capacitor C22 correspond to the second amplifier AMP2 of FIG. 5.

As described above, the zero controller 130A controls the gain g₂ of the second amplifier AMP2 corresponding to the low-gain broadband, according to the output current I_{OUT} of the regulator circuit 100. In FIG. 6, the zero controller 130A controls the gain (that is, transconductance gm₂) of the second transconductance amplifier 114 according to the output current I_{OUT} Specifically, the smaller the output current I_{OUT} is, the more the zero controller 130A will increase the transconductance gm₂.

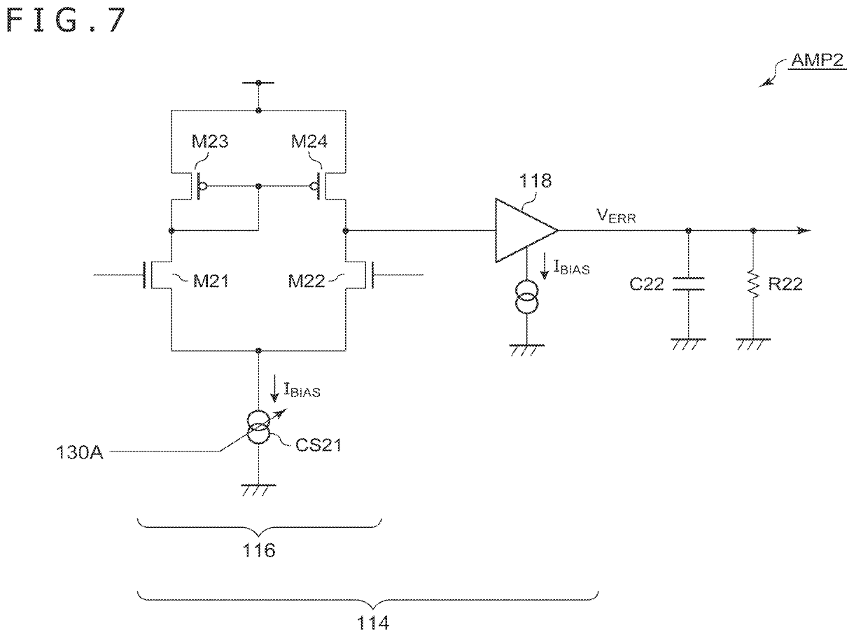

FIG. 7 is a circuit diagram illustrating a configuration example of the second amplifier AMP2. The second amplifier AMP2 includes a differential amplifier 116. The differential amplifier 116 includes an input differential pair M21 and M22, a bias current source (tail current source) CS21, and current mirror circuits M23 and M24 as loads of the input differential pair. The bias current source CS21 generates a bias current I_{BIAS} of the differential amplifier 116.

The zero controller 130A successively changes the bias current I_{BIAS} generated by the bias current source CS21, according to the output current I_{OUT} of the linear regulator circuit 100A. The bias current I_{BIAS} can be successively changed to successively move the zero point in association with the pole.

The zero controller 130A controls the bias current source CS21 such that the smaller the output current I_{OUT} of the regulator circuit 100 is, the more the bias current I_{BIAS} will increase. The bias current I_{BIAS} can be changed to change the gain of the differential amplifier 116 and eventually the transconductance gm₂ of the second transconductance amplifier 114.

The second transconductance amplifier 114 can further include an amplification stage 118 provided on a later stage of the differential amplifier 116. In this case, the bias current I_{BIAS} to be supplied to the amplification stage 118 can also be changed in conjunction with the bias current I_{BIAS} of the differential amplifier 116.

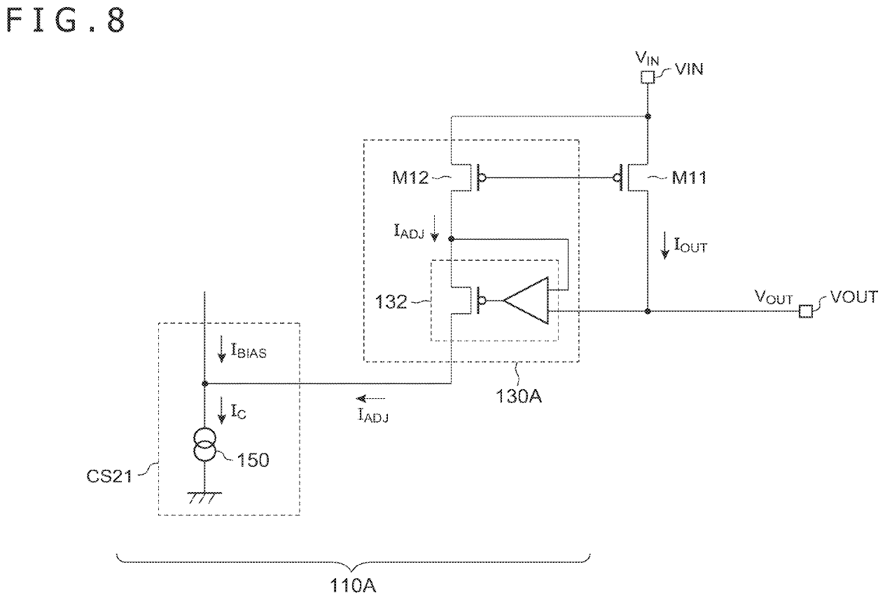

FIG. 8 is a circuit diagram illustrating a configuration example of the zero controller 130A. The zero controller 130A includes a transistor M12 that is a P-channel MOSFET with the gate and the source connected in common to the gate and the source of the output transistor M11. An adjustment current I_{ADJ} proportional to the output current I_{OUT} flowing through the output transistor M11 flows through the transistor M12. The zero controller 130A uses the adjustment current I_{ADJ} to change the bias current I_{BIAS} to be generated by the bias current source CS21.

In a case where the linear regulator circuit 100A is a low drop output (LDO) in which the potential of the input voltage V_{IN} and the output voltage V_{OUT} is significantly small, the output transistor M11 operates in a linear region with a significantly small drain-source voltage, and the difference between the drain-source voltage of the output transistor M11 and the drain-source voltage of the transistor M12 becomes large.

In that case, the zero controller 130A can include a stabilization circuit 132. The stabilization circuit 132 is designed such that the drain voltage of the transistor M12 becomes equal to the drain voltage (that is, output voltage V_{OUT}) of the output transistor M11. The stabilization circuit 132 includes, for example, a transistor M13 and an error amplifier 134, and the error amplifier 134 adjusts the gate voltage of the transistor M13 such that a drain voltage VD of the transistor M12 becomes equal to the output voltage V_{OUT}. In the case of LDO, an adjustment current I_{ADJ} proportional to the output current I_{OUT} can be obtained by the stabilization circuit 132 being added.

The bias current source CS21 includes, for example, a constant current source 150 that generates a constant current Ic. Connecting the output of the zero controller 130A to the bias current source CS21 allows the difference between the constant current Ic and the adjustment current I_{ADJ} to be supplied as the bias current I_{BIAS} to the differential amplifier 116 and the amplification stage 118. The bias current I_{BIAS} increases when the adjustment current I_{ADJ} decreases after a decrease in the output current I_{OUT}. On the other hand, the bias current I_{BIAS} decreases when the adjustment current I_{ADJ} increases after an increase in the output current I_{OUT}.

The configuration of the zero controller 130A and the bias current source CS21 is not limited to the configuration illustrated in FIG. 8.

### Second Embodiment

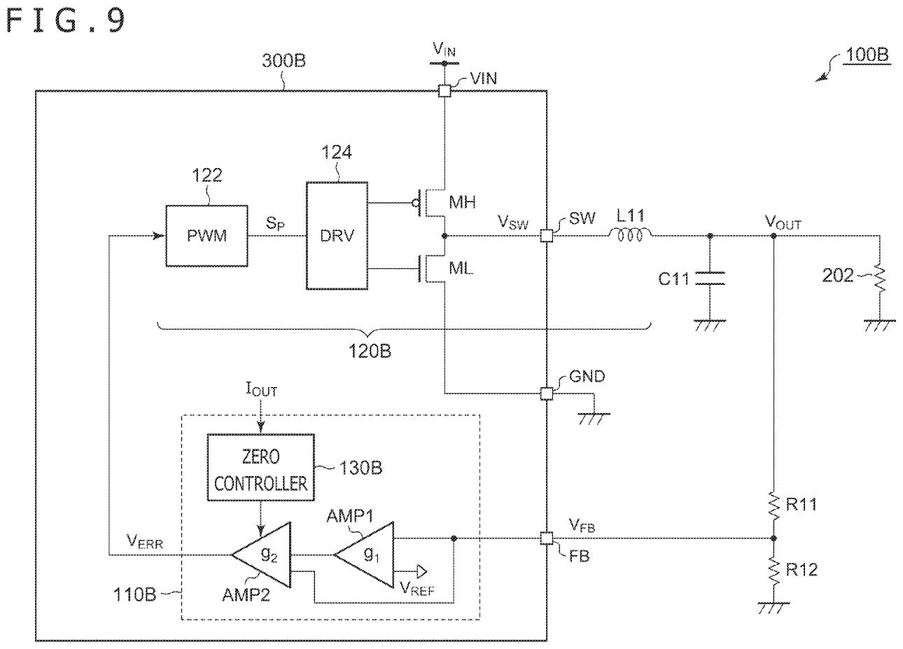

FIG. 9 is a circuit diagram of a regulator circuit (DC/DC converter 100B) according to a second embodiment. The DC/DC converter 100B includes a controller IC 300B that is a semiconductor chip and peripheral circuits of the controller IC 300B. The controller IC 300B may be a chip dedicated to the DC/DC converter 100B or may be part of a multi-channel power supply circuit such as a PMIC.

The controller IC 300B includes an input pin V_{IN}, a switching pin SW, a ground pin GND, and a feedback pin FB. An inductor L11 is connected to the switching pin SW.

The controller IC 300B includes an error amplifier 110B, a pulse modulator 122, a driver 124, a high side transistor MH, and a low side transistor ML. The pulse modulator 122, the driver 124, the high side transistor MH, the low side transistor ML, and the external inductor L11 correspond to the output stage 120 illustrated in FIG. 2. Note that the high side transistor MH and the low side transistor ML may be discrete elements.

The error amplifier 110B includes the first amplifier AMP1, the second amplifier AMP2, and a zero controller 130B that are connected in cascade.

The pulse modulator 122 generates a pulse signal Sp corresponding to the output V_{ERR} of the error amplifier 110B. The pulse modulator 122 is, for example, a pulse width modulator, and in that case, the duty cycle (pulse width) of a pulse signal Sp changes according to the output V_{ERR} of the error amplifier 110B. The pulse modulator 122 may be a pulse frequency modulator or may be other modulators. The pulse modulator 122 may be in a voltage mode or may be in a peak current mode or an average current mode.

The zero controller 130B controls the gain g₂ of the second amplifier AMP2 according to the output current I_{OUT} of the DC/DC converter 100B. The detection method of the output current I_{OUT} is not particularly limited to any kind. For example, the output current I_{OUT} may be detected according to the coil current flowing through the inductor L11. The output current I_{OUT} may be detected according to the current flowing through the high side transistor MH. The output current I_{OUT} may be detected according to the current flowing through the low side transistor ML. The controller IC 300B in general includes hardware (current detection circuit) that detects at least one of the coil current, the current of the high side transistor MH, and the current of the low side transistor ML. Hence, the zero controller 130B may control the error amplifier 110B according to the amount of current detected by the hardware described above.

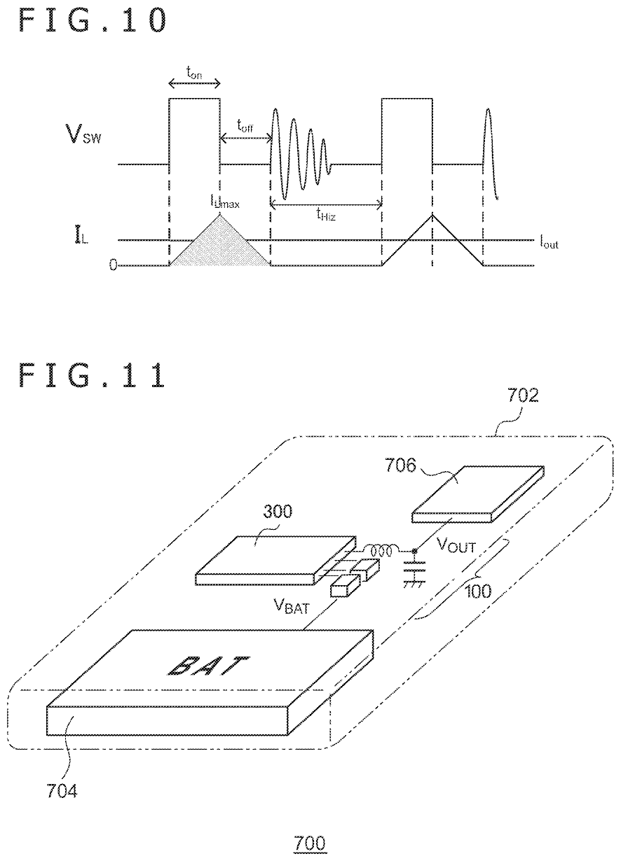

FIG. 10 is an operation waveform diagram of a buck DC/DC converter that operates in a DCM. FIG. 10 illustrates a voltage V_{SW} of the switching pin SW and a coil current I_{L}. In the DCM, the DC/DC converter 100B repeats three states including an on-state ON, an off-state OFF, and a high impedance state HiZ. In the on-state ON, the high side transistor MH is on, and the low side transistor ML is off. In the off-state OFF, the high side transistor MH is off, and the low side transistor ML is on. In the high impedance state HiZ, both the high side transistor MH and the low side transistor ML are off. In the DCM, as on-time tₒₙ changes, the average value of the coil current I_{L} increases, and the output current I_{OUT} changes. In the DC/DC converter 100B operating in the DCM, a transfer function with the on-time tₒₙ as an input and the output voltage V_{OUT} as an output is represented by the following Equation (1).

$$\begin{matrix}[ Math . 1 ] & \\ \frac{Δ {v}_{out}}{Δ {t}_{o n}} = \frac{{V}_{IN}}{2 ( {\overline{t}}_{on} + {\overline{t}}_{off} )} \times \frac{1}{1 + s \frac{RC}{2}} & ( 1 )\end{matrix}$$

R represents an impedance of the load 202, and C represents a capacitance of the output capacitor C11. That is, the DC/DC converter 100B also has a pole ωₚ corresponding to the impedance R of the load 202, as in the linear regulator.

According to the controller IC 300B illustrated in FIG. 9, when the pole ωₚ moves after a change in the load impedance, the error amplifier 110B can move the zero point of the error amplifier 110B in association with the movement. This can maintain the stability of the system.

The configuration of the error amplifier 110B and the zero controller 130B in the second embodiment can be similar to the configuration of the error amplifier 110A and the zero controller 130A described in the first embodiment.

### (Usage)

FIG. 11 depicts an example of an electronic device 700 including the regulator circuit 100 according to the embodiments. The electronic device 700 is, for example, a battery-powered device, such as a mobile phone terminal, a digital camera, a digital video camera, a tablet terminal, and a portable audio player. The electronic device 700 includes a housing 702, a battery 704, a microprocessor 706, and the regulator circuit 100. The regulator circuit 100 receives a battery voltage V_{BAT} (=V_{IN}) from the battery 704 through the input terminal and supplies the output voltage V_{OUT} to the microprocessor 706 or other loads connected to the output terminal. The regulator circuit 100 may be the linear regulator circuit 100A or the DC/DC converter 100B, and FIG. 11 illustrates an example of the DC/DC converter 100B.

The type of electronic device 700 is not limited to the battery-powered device. The electronic device 700 may be an in-vehicle device, may be OA equipment such as a facsimile, or may be industrial equipment.

The embodiments are illustrative, and those skilled in the art will understand that there can be various modifications for the combinations of the constituent elements and the processes of the embodiments. The modifications will be described.

### (Modification 1)

In FIG. 6, the resistance R22 in the second amplifier AMP2 converts the output current of the second transconductance amplifier 114 into the voltage signal V_{ERR}. Thus, the gain g₂ of the second amplifier AMP2 is proportional to the resistance R22. Accordingly, the zero controller 130 may change the resistance value of the second resistance R22 in addition to or in place of the transconductance gm₂ of the second transconductance amplifier 114.

### (Modification 2)

Although the gain g₂ of the second amplifier AMP2 is successively changed according to the output current I_{OUT} in the embodiments, the configuration is not limited to this. The gain g₂ of the second amplifier AMP2 may be discretely changed, and most simply, the gain g₂ of the second amplifier AMP2 may be changed in two stages. In the case of discretely changing the gain g₂ of the second amplifier AMP2, the bias current I_{BIAS} generated by the bias current source CS21 illustrated in FIG. 7 may be discretely changed. Alternatively, the sizes of the transistors M23 and M24 illustrated in FIG. 7 may be variable.

### (Modification 3)

Although the buck converter is described as an example of the switching regulator in relation to the second embodiment, the switching regulator is not limited to this, and the present technology can also be applied to a boost converter, a buck-boost converter, and other converters.

The embodiments are illustrative, and those skilled in the art will understand that there can be various modifications for the combinations of the constituent elements and the processes of the embodiments and that the modifications can be included in the present disclosure and the scope of the present technology.

What is claimed is:

1. A regulator circuit that supplies an output voltage to a load, the regulator circuit comprising:
an error amplifier that amplifies an error between a feedback signal corresponding to the output voltage and a reference voltage; and
an output stage that changes the output voltage according to an output of the error amplifier, wherein
the error amplifier includes
a first transconductance amplifier that receives the feedback signal and the reference voltage,
a first resistance connected to an output node of the first transconductance amplifier and a ground,
a first capacitor connected in parallel to the first resistance,
a second transconductance amplifier that receives a voltage of the output node of the first transconductance amplifier and the feedback signal,
a second resistance connected to an output node of the second transconductance amplifier and a ground,
a second capacitor connected in parallel to the second resistance, and
a zero controller that controls a gain of the second transconductance amplifier according to an output current of the regulator circuit.

2. The regulator circuit according to claim 1, wherein
the zero controller successively changes a bias current of the second transconductance amplifier according to the output current of the regulator circuit.

3. The regulator circuit according to claim 1, wherein
the smaller the output current of the regulator circuit is, the more the zero controller will increase the bias current of the second transconductance amplifier.

4. The regulator circuit according to claim 1, wherein
the regulator circuit is a linear regulator circuit,
the output stage includes an output transistor, and
the zero controller includes
a first transistor with a gate and a source connected in common to a gate and a source of the output transistor, and
a correction current generation circuit that generates a correction current corresponding to a current flowing through the first transistor and that supplies the correction current to the second transconductance amplifier.

5. The regulator circuit according to claim 1, wherein
the regulator circuit is a direct current/direct current converter, and
the zero controller successively changes the bias current of the second transconductance amplifier according to an output current of the direct current/direct current converter when the direct current/direct current converter operates in a discontinuous conduction mode.

6. A regulator circuit that supplies an output voltage to a load, the regulator circuit comprising:
an error amplifier that amplifies an error between a feedback signal corresponding to the output voltage and a reference voltage; and
an output stage that changes the output voltage according to an output of the error amplifier, wherein
the error amplifier includes
a first amplifier of a high-gain narrow-band and a second amplifier of a low-gain broadband that are connected in cascade, and
a zero controller that controls a gain of the second amplifier according to an output current of the regulator circuit.

7. The regulator circuit according to claim 6, wherein
the second amplifier includes
a second transconductance amplifier,
a second resistance connected to an output node of the second transconductance amplifier and a ground, and
a second capacitor connected in parallel to the second resistance.

8. The regulator circuit according to claim 7, wherein
the zero controller controls a gain of the second transconductance amplifier according to the output current of the regulator circuit.

9. The regulator circuit according to claim 7, wherein
the zero controller controls an impedance of the second resistance according to the output current of the regulator circuit.

10. The regulator circuit according to claim 1, wherein
the regulator circuit is integrated into one semiconductor substrate.

11. A control circuit of a direct current/direct current converter, the control circuit comprising:
an error amplifier that amplifies an error between a feedback signal corresponding to an output voltage of the direct current/direct current converter and a reference voltage; and
a pulse modulator that generates a pulse signal according to an output of the error amplifier, wherein
the error amplifier includes
a first transconductance amplifier that receives the feedback signal and the reference voltage,
a first resistance and a first capacitor that are connected in parallel to an output node of the first transconductance amplifier and a ground,
a second transconductance amplifier that receives a voltage of the output node of the first transconductance amplifier and the feedback signal,
a second resistance connected to an output node of the second transconductance amplifier,
a second capacitor connected to the output node of the second transconductance amplifier, in parallel to the second resistance, and
a zero controller that controls a gain of the second transconductance amplifier according to an output current of the direct current/direct current converter.

12. A control circuit of a direct current/direct current converter, the control circuit comprising:
an error amplifier that amplifies an error between a feedback signal corresponding to an output voltage of the direct current/direct current converter and a reference voltage; and
a pulse modulator that generates a pulse signal according to an output of the error amplifier, wherein
the error amplifier includes
a first amplifier of a high-gain narrow-band and a second amplifier of a low-gain broadband that are connected in cascade, and
a zero controller that controls a gain of the second amplifier according to an output current of the converter.

13. The control circuit according to claim 12, wherein
the second amplifier includes
a second transconductance amplifier,
a second resistance connected to an output node of the second transconductance amplifier and a ground, and
a second capacitor connected in parallel to the second resistance.

14. The control circuit according to claim 11, wherein
the zero controller controls a gain of the second transconductance amplifier according to the output current of the direct current/direct current converter.

15. The control circuit according to claim 11, wherein
the zero controller controls an impedance of the second resistance according to the output current of the direct current/direct current converter.

16. The control circuit according to claim 11, wherein
the control circuit is integrated into one semiconductor substrate.
